(19) United States
(12) Patent Application Publication
(10) Pub. No.: US 2016/0093364 A1
(43) Pub. Date: Mar. 31, 2016

(54) SELECTIVE CURRENT BOOSTING IN A STATIC RANDOM-ACCESS MEMORY

(71) Applicant: QUALCOMM Incorporated, San Diego, CA (US)

(72) Inventors: Seong-Ook JUNG, Seoul (KR); Younghwi YANG, Seoul (KR); Stanley Seungchul SONG, San Diego, CA (US); Zhongze WANG, San Diego, CA (US); Choh Fei YEAP, San Diego, CA (US)

(21) Appl. No.: 14/499,147

(22) Filed: Sep. 27, 2014

(51) Int. Cl. G11C 11/419

(52) U.S. Cl. CPC G11C 11/419

(57) ABSTRACT

Systems and methods include a static random-access memory (SRAM) bit cell circuit having an access transistor configured to pass a read current to a storage node, the access transistor including an access transistor back gate. The access transistor back gate is biased to enable selective current boosting of the read current during a read operation.

### FIELD OF DISCLOSURE

Embodiments relate to bit cell circuits and methods of operating a non-volatile memory element. In particular, the embodiments relate to selective current boosting using back gate transistors in static random-access memory (SRAM).

### BACKGROUND

Memory devices conventionally include arrays of bit cells that each store a bit of data. Each data bit can represent a logical zero (“0”) or a logical one (“1”), which may correspond to a state of the bit cell. During a read operation of a selected bit cell, a voltage level close to ground may be representative of “0” and a relatively higher voltage level may be representative of “1”.

FIG. 1 illustrates a conventional six-transistor static random-access memory (6T SRAM) bit cell 100. The bit cell 100 comprises a pair of cross-coupled inverters, each cross-coupled inverter comprising a p-channel metal oxide semiconductor (PMOS) pull-up transistor and an n-channel metal oxide semiconductor (NMOS) pull-down transistor separated by a storage node. In a read operation of bit cell 100, the bit lines BL and BL_{B} are both pre-charged such that they respectively carry a bit line charge. Then the word line WL is set to a high-voltage state in order to select bit cell 100, which turns on transistors PG and PG_{B}. If a the 6T SRAM stores a logical “1,” without loss of generality, a logical “1” appears at Node Q of the first inverter and a logical “0” appears at Node Q_{B} of the second inverter. By turning on the transistors PG and PG_{B} the voltage on the bit line BL will be maintained by the pull-up transistor PU₁, whereas the voltage on the bit line BL_{B} will be discharged by the pull-down transistor PD₂. Sense amplifiers (not shown) are used to amplify the differential voltage which appears on bit lines BL and BL_{B}, and a logical value of “1” is read. On the other hand, if a logical “0” is stored in bit cell 100, a logical “0” appears at Node Q and a logical “1” appears at Node Q_{B}. Reading bit cell 100 results in the opposite of the above process, in the sense that bit line BL will be discharged and bit line BL_{B} will be charged to a high voltage, eventually leading to a logical value of “0” being read.

As memory devices becomes smaller, a problem arises in that their reliability and performance decrease. As bit cells become smaller, size constraints can reduce the read stability of the bit cells, causing them to become more sensitive to noise resulting from, for example, temperature changes or process variations. For example, a static noise margin (SNM) is defined as the minimum noise voltage (as measured between Node Q and Node Q_{B}) which is capable of inadvertently flipping the state of the bit cell.

A read static noise margin (RSNM) is defined as the amount of noise voltage capable of inadvertently flipping the bit cell state during a read operation of the bit cell. A bit cell with high read stability resists inadvertent flipping during a read operation. This phenomenon of inadvertent flipping during a read operation is known as read disturbance.

Read stability is correlated to a bit cell parameter known as beta ratio β. The ratio β is defined in terms of the width to length ratio (W/L ratio) of the bit cell's pull-down transistors divided by the W/L ratio of the bit cell's access transistors. In a typical 6T SRAM, the transistor lengths are equal. But the width of the pull-down transistors is high relative to the width of the access transistors. Therefore, β exceeds one and the read stability of the bit cell is correspondingly high.

The effect of β on read stability will be explained in accordance with the 6T SRAM bit cell 100 of FIG. 1. In bit cell 100, a low voltage at Node Q indicates that the bit cell stores a logical “0”. When the bit cell is subjected to a read operation, the bit lines BL and BL_{B} will be pre-charged to a high-voltage state and the word line WL will be set to a high-voltage state, turning on access transistors PG and PG_{B}. In the scenario where the bit cell stores a logical “0” at Node Q, a current I_{READ} is permitted to flow from the bit line BL to Node Q (via PG), and from Node Q to ground (via PD₁). As current I_{READ} flows from bit line BL to ground via transistors PG and PD₁, a voltage appears between the transistors (at Node Q) as a result of the voltage divider effect. In a first scenario, the W/L ratio of PD₁ is high relative to the W/L ratio of PG (i.e., the β value is high). Because PD₁ has greater width than PG, it will have a smaller effective resistance than PG. Accordingly, the voltage induced at Node Q will be low and therefore unlikely to cause a read disturbance. In a second scenario, by comparison, the widths of PD₁ and PG are relatively equal. Here, the voltage induced at Node Q will be relatively higher than the voltage induced in the first scenario. As noted above, a high voltage at Node Q, particularly, a voltage that exceeds the RSNM, can cause a read disturbance.

Despite the danger of read disturbance, there is an increasing need to reduce the width of transistors. In particular, there is increasing need to reduce the width of the widest transistors, i.e., pull-down transistors PD₁ and PD₂. Various schemes have been proposed for striking a balance between read stability and bit cell size.

One approach has been to provide a read assist circuit which is operated in accordance with a word line underdrive (WLUD) scheme. In a WLUD scheme, the voltage applied to the gate of the access transistors during a read operation (via the word line WL) is reduced. Accordingly, the current I_{READ} flowing through the transistors during a read operation is reduced, as is the voltage induced at Node Q. When the induced voltage at Node Q is reduced, the likelihood of a read disturbance is also reduced. By following a WLUD scheme, read stability can be achieved despite low β values.

However, if the current I_{READ} is reduced, the voltage on the bit line BL takes a longer time to discharge through the bit cell. A new danger arises in that bit line BL may not discharge in the allotted read time and a read error occurs in that the data stored in bit cell 100 is not properly read. This danger must be mitigated by increasing the time allotted for reading the bit cell.

Therefore, in a WLUD scheme, increased read stability comes at the cost of increased read time. A new solution is needed in which read stability can be maintained without increasing read time.

### SUMMARY

In one aspect, the present disclosure provides an SRAM bit cell circuit comprising an access transistor configured to pass a read current to a storage node, the access transistor comprising an access transistor back gate, wherein the access transistor back gate is biased to enable selective current boosting of the read current during a read operation.

In another aspect, the present disclosure provides a method for operating an SRAM bit cell circuit, the method comprising supplying a read current to a storage node during a read operation, wherein the read current is passed through an access transistor comprising an access transistor back gate, and biasing the access transistor back gate to enable selective current boosting of the read current during the read operation.

In yet another aspect, the present disclosure provides an SRAM bit cell comprising means for passing a read current to a storage node during a read operation, and means for biasing the means for passing a read current to enable selective current boosting of the read current during the read operation.

### BRIEF DESCRIPTION OF THE DRAWINGS

The accompanying drawings are presented to aid in the description of embodiments are provided solely for illustration of the embodiments and not limitation.

FIG. 1 illustrates a schematic diagram of a conventional 6T SRAM.

FIG. 2 illustrates a high-level diagram of a memory device and a control device according to an exemplary aspect.

FIG. 3 illustrates a procedure for controlling a memory device according to an exemplary aspect.

FIG. 4 illustrates a schematic of a six-transistor static random-access memory (6T SRAM) with back gate control of four transistors according to an exemplary aspect.

FIG. 5 illustrates a schematic of a six-transistor static random-access memory (6T SRAM) with back gate control of six transistors according to an exemplary aspect.

FIG. 6 illustrates a procedure for operating a memory device according to an exemplary aspect.

FIG. 7 illustrates a high-level diagram of a wireless device that includes a memory array according to an exemplary aspect.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The words “exemplary” and/or “example” are used herein to mean “serving as an example, instance, or illustration.” Any embodiment described herein as “exemplary” and/or “example” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an”, and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

As memory devices become smaller, conventional 6T SRAM bit cells exhibit a decreasing read static noise margin (RSNM). According to a WLUD approach, the current I_{READ}, used to discharge the bit lines during a read operation, is reduced, thereby decreasing the likelihood that I_{READ} will induce a voltage at a storage node, and improving the RSNM. However, the WLUD scheme increases the amount of time necessary to properly read the bit cell. By selectively boosting current that flows through the transistors composing the bit cell, read time can be reduced without sacrificing read stability.

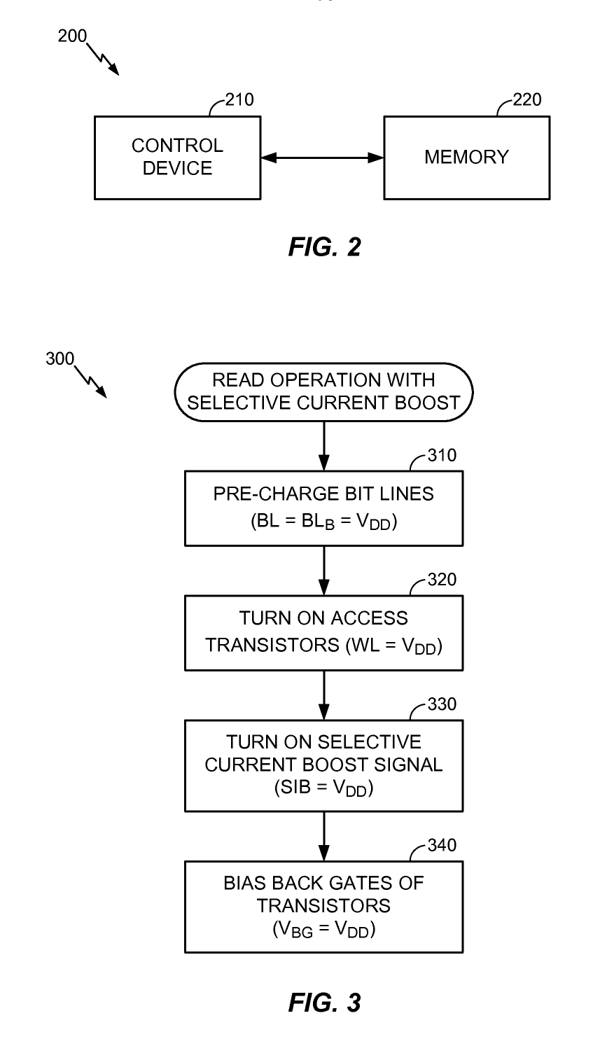

FIG. 2 generally illustrates a system 200 for reading and/or writing a memory 220. In the system 200, a control device 210 sends memory control signals to the memory 220. Memory 220 may comprise an array of bit cells which are arranged in rows and columns. The memory control signals may comprise read commands, write commands, data addresses which identify one or more of a row, a column, and/or a specific bit cell, and/or other signals which control the operations of memory 220.

FIG. 3 generally illustrates a read operation procedure 300 using selective current boosting (SIB). The procedure 300 may be performed by a control device such as control device 210. The control device 210 performs the procedure 300 by sending read commands, write commands, data addresses which identify one or more of a row, a column, and/or a specific bit cell, and/or other signals to memory 220.

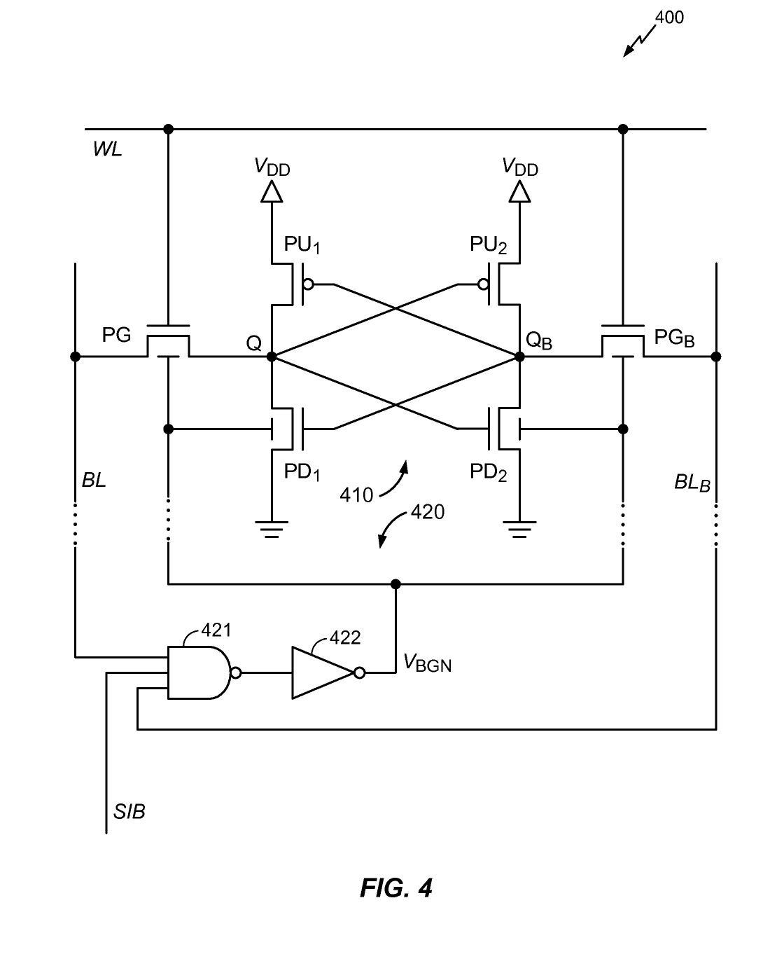

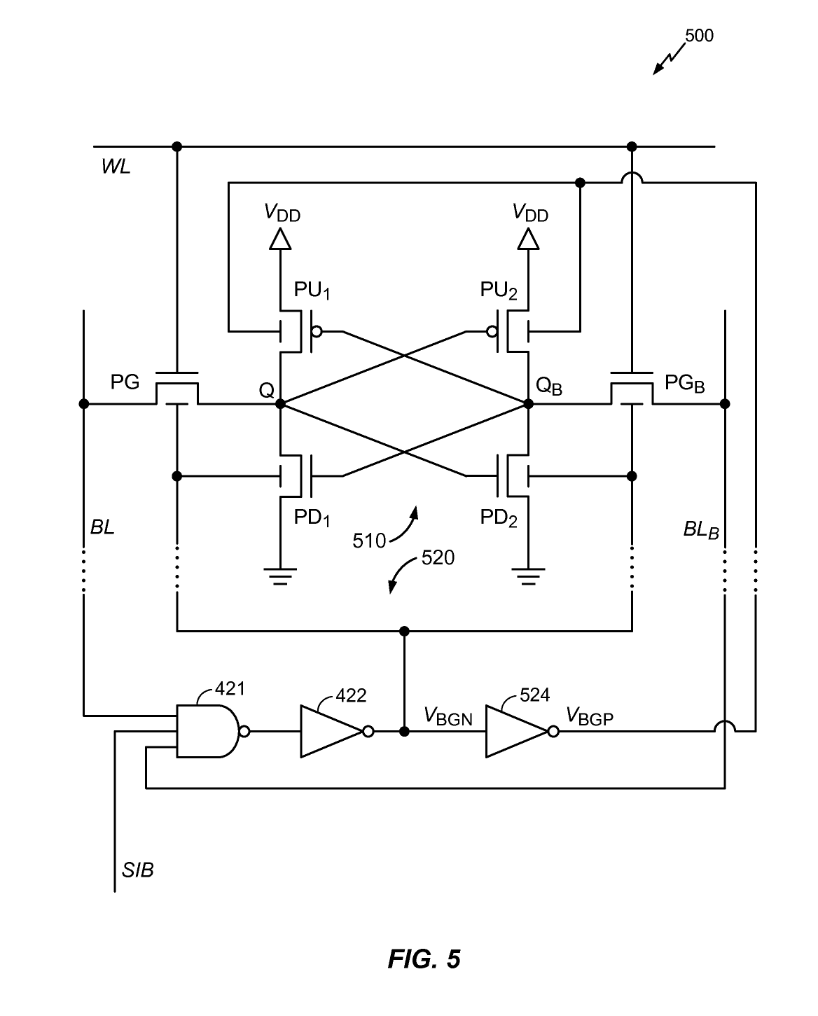

At 310, the bit lines of a selected bit cell in memory 220 are pre-charged with a high voltage such that they carry a bit line charge. When pre-charging 310 is complete, the read operation procedure 300 proceeds to 320, where the word line of the selected bit cell is set to a high-voltage state, which turns on the access transistors. After the access transistors are turned on, the read operation procedure 300 proceeds to 330, where the selective current boost signal SIB is set to a high-voltage state. In block 340, setting the boost signal SIB to a high-voltage state results in a bias being applied to the back gates of the access transistors and transistors composing the bit cell as will be further described with reference to FIGS. 4 and 5. Although in this aspect the boost signal SIB is described as being active when in a high-voltage state, those having skill in the art will readily comprehend that other aspects where this and other signals are active when in a low-voltage state are within the scope of the present disclosure, and may be arrived at without undue experimentation.

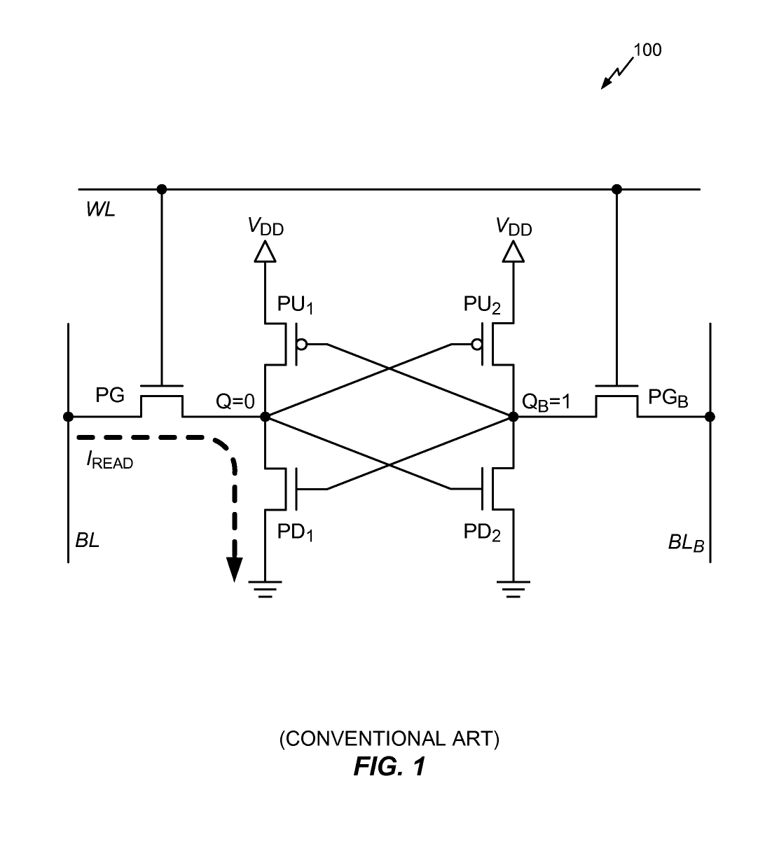

FIG. 4 generally illustrates a schematic of a circuit 400 comprising a 6T SRAM circuitry 410 and associated control circuitry 420. The 6T SRAM circuitry 410 has the same components as bit cell 100 of FIG. 1. However, the access transistors PG and PG_{B} and the pull-down transistors PD₁ and PD₂ are equipped with back gates. The back gates are coupled to the control circuitry 420.

The control circuitry 420 comprises a NAND gate 421 with three inputs. The three inputs of the NAND gate 421 include the bit lines BL and BL_{B} as well as a selective current boost signal SIB. NAND gate 421 has a trip level V_{TRIP} such that it outputs a logical “0” if the respective voltages of each of the three input signals exceeds trip level V_{TRIP}. If any of the three input signals does not exceed trip level V_{TRIP}, then NAND gate 421 outputs a logical “1”. The output of the NAND gate 421 is coupled to the input of an inverter 422 which outputs a back gate bias signal V_{BGN}. The bias signal V_{BGN} is coupled to the back gates of access transistors PG and PG_{B} and pull-down transistors PD₁ and PD₂.

The effect of read operation procedure 300 will be explained in accordance with the 6T SRAM bit cell 410 of FIG. 4. In the following illustrations, it is assumed that read operation procedure 300 targets bit cell 410 for a read operation and that a logical “0” and logical “1” are stored at Node Q and Node Q_{B}, respectively, of bit cell 410.

In a first scenario, it is assumed that during read operation procedure 300, BL discharges slowly relative to a desired read time parameter of the memory device 220 (i.e., I_{READ} is small). Slow discharge may be the result of, for example, process variation in one or more of transistors PG and PD₁. In this scenario, pre-charging as in 310 is completed and the access transistor PG is turned on as in 320. During 310, in which the bit lines BL and BL_{B} are pre-charged, the voltages associated with bit lines BL and BL_{B} increase. By the time 320 begins, the voltages associated with bit lines BL and BL_{B} have exceeded trip level V_{TRIP}. However, because 330 has not begun, the SIB input of NAND gate 432 remains in a low-voltage state. As a result, the output of the NAND gate 421 is a logical “1”, the output of the inverter 422 is a logical “0”, and no voltage is applied to the back gates of the transistors in the bit cell 410.

Because a logical “0” is stored at Node Q, bit line BL begins to discharge via transistors PG and PD₁. Bit line BL_{B}, by contrast, remains at a logical “1”. It will be understood that as BL discharges, the input to NAND gate 421 from bit line BL will drop accordingly. Depending on the set length of time between the completion of 320 (in which the access transistor PG is turned on) and the commencement of 330 (in which the selective current boost signal SIB is set to a high voltage), the bit line BL may or may not have discharged such that the voltage on bit line BL is below trip level V_{TRIP}. In this first scenario, however, we assume that bit line BL discharges slowly. Accordingly, the voltage on bit line BL still exceeds trip level V_{TRIP} when selective current boost signaling 330 begins.

Therefore, when 330 begins, the SIB input of NAND gate 421 is set to a high-voltage state that exceeds trip level V_{TRIP}, and, since all three inputs of NAND gate 421 exceed trip level V_{TRIP}, the output of NAND gate 421 flips to logical “0”. The logical “0” output from NAND gate 421 is inverted by inverter 422. Accordingly, the bias signal V_{BGN} output by inverter 422 flips to a logical “1”. This voltage, applied to the back gates of access transistor PG and pull-down transistor PD₁, boosts the current I_{READ} flowing through transistors PG and PD₁. As a result, bit line BL begins to discharge more quickly, and the danger of a read error is mitigated.

If the turning-on of the access transistor at 320 and the selective current boost signaling at 330 begin at the same time, then every read operation will result in a current boost applied to the back gates of access transistors PG and PG_{B} and pull-down transistors PD₁ and PD₂. However, current boosting may not be needed for all bit cells since not every bit cell 410 will exhibit slow discharge of the bit lines during a read operation. For example, in an array of bit cells such as in memory device 220, one bit cell may exhibit a satisfactory read current I_{READ} while another bit cell, possibly due to process variation, exhibits a low read current I_{READ}, and a slow discharge of the bit lines. Accordingly, only the bit cells which exhibit slow discharge (and potential read error) are in need of current boosting. The read operation procedure 300 can therefore observe a delay time T_{SIB} between the turning-on of the access transistor at 320 and the selective current boost signaling at 330. The delay time T_{SIB} commences when the access transistor PG is turned on, or alternatively, when the gate of the access transistor PG is biased. If T_{SIB} is zero, then access transistor turn-on 320 and selective current boost signaling 330 begin simultaneously. As the delay T_{SIB} increases, the time in which the bit line BL is allowed to discharge at its normal (non-boosted) rate increases. If the voltage on bit line BL still exceeds trip level V_{TRIP} when the delay T_{SIB} has expired, then the selective current boost signaling 330 will result in the flipping of NAND gate 421 and the boosting of I_{READ} using a high-voltage bias signal V_{BGN}. If delay T_{SIB} is shortened, then selective current boosting becomes more likely since the bit line BL will have less time to discharge. Therefore, T_{SIB} can be optimized based on the design parameters of the memory device 220.

Relatedly, trip level V_{TRIP} can also be optimized based on design parameters of the memory device 220. If trip level V_{TRIP} is equal to supply voltage V_{DD}, then any amount of discharge from either bit line will prevent NAND gate 421 from outputting a logical “0”. As trip level V_{TRIP} decreases, it becomes increasingly likely that the voltage on one bit line or the other will be greater than trip level V_{TRIP} when the delay T_{SIB} is over, thereby triggering current boosting of I_{READ}.

In the foregoing scenario, it was assumed that bit line BL discharged at a low speed due to, for example, process variation. In a second scenario, it is assumed that during read operation procedure 300, bit line BL discharges at an adequate speed. In this scenario, pre-charging as in 310 is completed and the access transistor PG is turned on as in 320. At the moment that access transistor PG is turned on, the NAND gate 421 is already receiving (due to pre-charging 310) a high-voltage input from the bit lines BL and BL_{B}. However, because bit line BL is discharging at an adequate speed in this scenario, the voltage at bit line BL drops below trip level V_{TRIP} prior to the commencement of selective current boost signaling at 330. Accordingly, when the selective current boost signal SIB is set to a high voltage (exceeding trip level V_{TRIP}), the output of NAND gate 421 nevertheless remains high because the voltage at bit line BL has already dropped below trip level V_{TRIP}. Therefore, bias signal V_{BGN} remains low, and bit cell 410 is not subjected to current boosting.

In some scenarios, circuitry 400 of FIG. 4, which boosts the current I_{READ} flowing through one node of bit cell 410, can cause a read disturbance in the opposing node of bit cell 410. For example, if bit line BL discharges through Node Q, which stores a logical “0”, and a current boost is applied to the bit cell, then a high bias signal V_{BGN} will be output to both PD₁ and PD₂. As a result, the possibility arises that the logical “1” stored at Node Q_{B} discharges through PD₂, thereby causing a read disturbance. However, FIG. 5 illustrates a circuitry that can be used to prevent such a read disturbance.

FIG. 5 generally illustrates a schematic of a circuitry 500 comprising a 6T SRAM bit cell 510 and associated control circuitry 520. The bit cell 510 has the same components as bit cell 410 of FIG. 4. In particular, the access transistors PG and PG_{B} and the pull-down transistors PD₁ and PD₂ are equipped with back gates. However, in bit cell 510, the pull-up transistors PU₁ and PU₂ are also equipped with back gates. The back gates of every transistor in bit cell 510 are coupled to the output of the associated control circuitry 520.

Like control circuitry 420, control circuitry 520 comprises a NAND gate 421 with three inputs. The three inputs of the NAND gate 421 include the bit lines BL and BL_{B} as well as a selective current boost signal SIB. The output of the NAND gate 421 is coupled to the input of an inverter 422 which outputs a bias signal V_{BGN}. The bias signal V_{BGN} is coupled to the back gates of access transistors PG and PG_{B} and pull-down transistors PD₁ and PD₂.

However, control circuitry 520 further comprises an additional inverter 524 coupled to the output of inverter 422. The inverter 524 inverts the bias signal V_{BGN} and outputs a bias signal V_{BGP}. The bias signal V_{BGP} is coupled to the back gates of pull-up transistors PU₁ and PU₂.

Unlike the circuitry 400 of FIG. 4, which may exhibit read disturbance in some scenarios, the circuitry 500 of FIG. 500 can advantageously reduce the likelihood of read disturbance by applying a current boost to the pull-up transistors PU₁ and PU2 as well as the pull-down transistors PD₁ and PD₂.

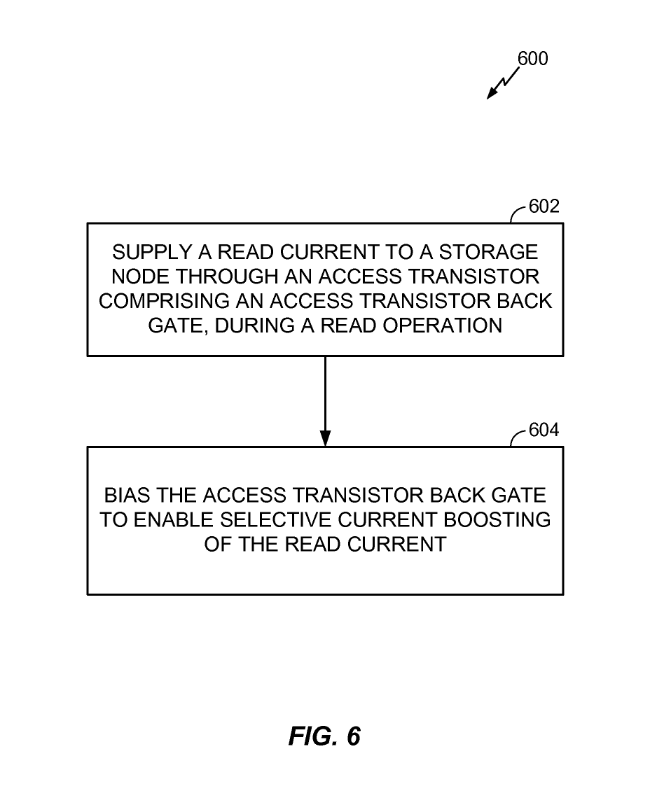

Accordingly, it will be appreciated that aspects include various methods for performing the processes, functions and/or algorithms disclosed herein. For example, as illustrated in FIG. 6, an aspect can include a method (600) for operating SRAM bit cell circuitry (e.g., 400, FIG. 4 or 500, FIG. 5). The method comprises: supplying a read current to a storage node (e.g., 410, FIG. 4) during a read operation, wherein the read current is passed through an access transistor (e.g., PG, FIG. 4) comprising an access transistor back gate—Block 602; and biasing the access transistor back gate (e.g., using control circuit 420) to enable selective current boosting of the read current during the read operation—Block 604. The method can further include biasing pull-down and pull-up transistor back gates as described in reference to FIGS. 4 and 5.

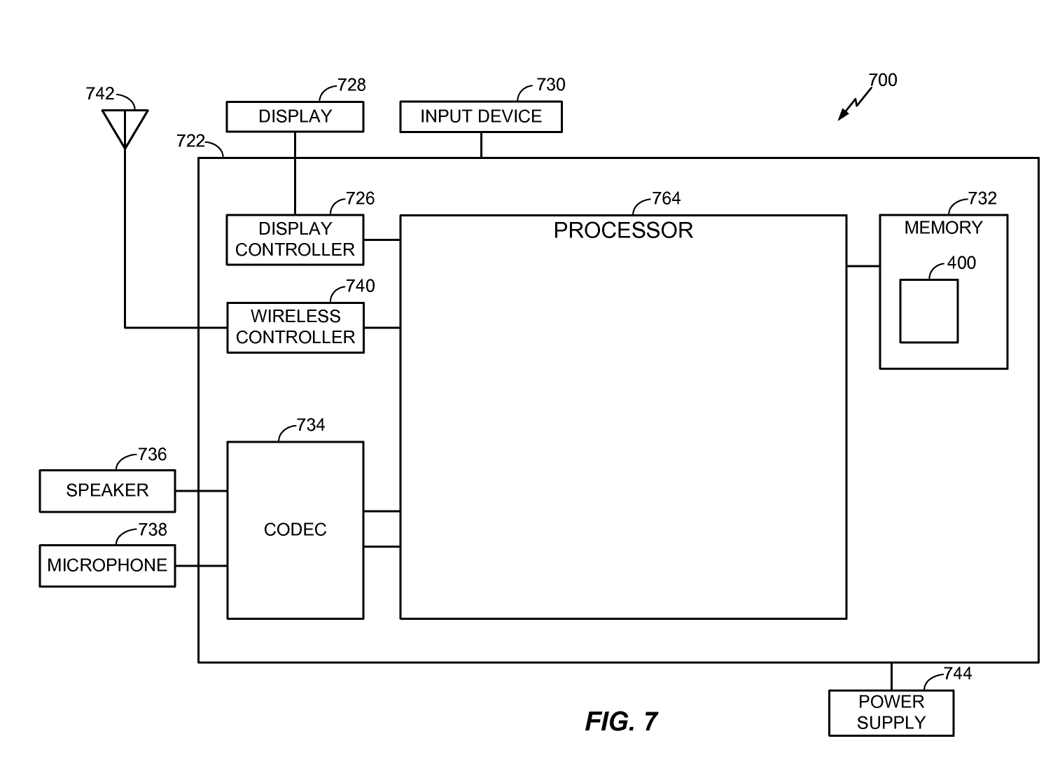

Referring to FIG. 7, a block diagram of a particular illustrative aspect of a wireless device that includes a processor configured according to exemplary aspects is depicted and generally designated 700. The device 700 includes a processor 764 coupled to a memory 732. FIG. 7 also shows display controller 726 that is coupled to processor 764 and to display 728. Coder/decoder (CODEC) 734 (e.g., an audio and/or voice CODEC) can be coupled to processor 764. Other components, such as wireless controller 740 (which may include a modem) are also illustrated. Speaker 736 and microphone 738 can be coupled to CODEC 734. FIG. 7 also indicates that wireless controller 740 can be coupled to wireless antenna 742. In a particular aspect, processor 764, display controller 726, memory 732, CODEC 734, and wireless controller 740 are included in a system-in-package or system-on-chip device 722. The memory 732 may comprise the circuitry 400 of FIG. 4 or the circuitry 500 of FIG. 5. Additionally or alternatively, processor 764 may include another memory structure, such as a cache or a register file (not shown) which comprise circuitry 400 of FIG. 4 or the circuitry 500 of FIG. 5.

In a particular aspect, input device 730 and power supply 744 are coupled to the system-on-chip device 722. Moreover, in a particular aspect, as illustrated in FIG. 7, display 728, input device 730, speaker 736, microphone 738, wireless antenna 742, and power supply 744 are external to the system-on-chip device 722. However, each of display 728, input device 730, speaker 736, microphone 738, wireless antenna 742, and power supply 744 can be coupled to a component of the system-on-chip device 722, such as an interface or a controller.

It should be noted that although FIG. 7 depicts a wireless communications device, processor 764 and memory 732 may also be integrated into a set-top box, a music player, a video player, an entertainment unit, a navigation device, a personal digital assistant (PDA), a fixed location data unit, or a computer. A processor (e.g., processor 764) may also be integrated into such a device.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A static random-access memory (SRAM) bit cell circuit comprising:
an access transistor configured to pass a read current to a storage node, the access transistor comprising an access transistor back gate;
wherein the access transistor back gate is biased to enable selective current boosting of the read current during a read operation.

2. The SRAM bit cell circuit of claim 1, further comprising:
a pull-down transistor coupled to the storage node, the pull-down transistor comprising a pull-down transistor back gate;
wherein the pull-down transistor back gate is biased to enable selective current boosting of the read current during the read operation.

3. The SRAM bit cell circuit of claim 1, further comprising:
a control circuit coupled to the access transistor back gate, the control circuit configured to output a bias signal to the access transistor back gate;
a pull-up transistor coupled to the storage node, the pull-up transistor comprising a pull-up transistor back gate;
wherein the control circuit is further coupled to the pull-up transistor back gate, and further configured to bias the pull-up transistor back gate during the read operation.

4. The SRAM bit cell circuit of claim 1, further comprising:
a control circuit coupled to the access transistor back gate, the control circuit configured to output a bias signal to the access transistor back gate.

5. The SRAM bit cell circuit of claim 4, further comprising:
a pull-down transistor coupled to the storage node, the pull-down transistor comprising a pull-down transistor back gate;
wherein the control circuit is further coupled to the pull-down transistor back gate, and further configured to bias the pull-down transistor back gate so as to enable selective current boosting of the read current during the read operation.

6. The SRAM bit cell circuit of claim 4, further comprising:
a bit line coupled to the access transistor, the bit line carrying a bit line charge; and
a selective current boost signal line, the selective current boost signal line carrying a selective current boost signal; wherein:
the control circuit is configured to output the bias signal if each of a plurality of signals coupled to the input of the control circuit exceeds a trip level;
the control circuit is configured not to output the bias signal if any of the plurality of signals coupled to the input of the control circuit does not exceed the trip level; and
the plurality of signals comprise the bit line charge and selective current boost signal.

7. The SRAM bit cell circuit of claim 6, wherein:
a delay time commences when the gate of the access transistor is biased so as to turn on the access transistor; and
the selective current boost signal does not exceed the trip level until the delay time has expired.

8. The SRAM bit cell circuit of claim 6, wherein the access transistor comprising an access transistor back gate comprises a first access transistor having a first access transistor back gate, the storage node comprises a first storage node, the bit line carrying a bit line charge comprises a first bit line carrying a first bit line charge, and the bit cell further comprises:
a second access transistor coupled to a second storage node, the access transistor comprising a second access transistor back gate; and
a second bit line carrying a second bit line charge coupled to the second access transistor and further coupled to the input of the control circuit.

9. The SRAM bit cell circuit of claim 8, wherein the plurality of signals comprise the first bit line charge, the second bit line charge, and the selective current boost signal.

10. The SRAM bit cell circuit of claim 9, wherein:
a delay time commences when the first access transistor back gate and the second access transistor back gate are biased so as to turn on the first access transistor and second access transistor, respectively; and
the selective current boost signal does not exceed the trip level until the delay time has expired.

11. A method for operating a static random-access memory (SRAM) bit cell circuit comprising:
supplying a read current to a storage node during a read operation, wherein the read current is passed through an access transistor comprising an access transistor back gate; and
biasing the access transistor back gate to enable selective current boosting of the read current during the read operation.

12. The method of claim 11, further comprising:
biasing a pull-down transistor back gate of a pull-down transistor to enable selective current boosting of the read current during the read operation, wherein the pull-down transistor is coupled to the storage node.

13. The method of claim 11, further comprising:
biasing a pull-up transistor back gate of a pull-up transistor during the read operation, wherein the pull-up transistor is coupled to the storage node.

14. The method of claim 11, further comprising:
outputting a bias signal from a control circuit, wherein the control circuit is coupled to the access transistor back gate.

15. The method of claim 14, further comprising:
outputting a bias signal from the control circuit, wherein the control circuit is coupled to the pull-down transistor back gate; and
biasing a pull-down transistor back gate of a pull-down transistor to enable selective current boosting of the read current during the read operation, wherein the pull-down transistor is coupled to the storage node.

16. The method of claim 14, further comprising:
outputting the bias signal if each of a plurality of signals coupled to an input of the control circuit exceeds a trip level; and
not outputting the bias signal if any of the plurality of signals coupled to the input of the control circuit does not exceed the trip level;
wherein a bit line charge and a selective current boost signal compose the plurality of signals, the bit line charge being carried on a bit line coupled to the access transistor, and the selective current boost signal being carried on a selective current boost signal line.

17. The method of claim 16, further comprising observing a delay time, wherein:
the delay time commences when a gate of the access transistor is biased so as to turn on the access transistor, and
the selective current boost signal does not exceed the trip level until the delay time has expired.

18. The method of claim 16, wherein:
the access transistor comprising an access transistor back gate comprises a first access transistor having a first access transistor back gate, the storage node comprises a first storage node, and the bit line carrying a bit line charge comprises a first bit line carrying a first bit line charge, and
the first bit line charge, a second bit line charge, and the selective current boost signal compose the plurality of signals, wherein the second bit line charge is carried on a second bit line coupled to a second storage node via a second access transistor.

19. The method of claim 16, wherein the control circuit comprises a NAND gate, and the plurality of signals are coupled to the input of the NAND gate.

20. The method of claim 16, wherein the control circuit comprises an inverter, and the bias signal is the output of the inverter.

21. A static random-access memory (SRAM) bit cell circuit comprising:
means for passing a read current to a storage node during a read operation; and
means for biasing the means for passing a read current to enable selective current boosting of the read current during the read operation.

22. The SRAM bit cell circuit of claim 21, further comprising:
means for discharging current from the storage node during a read operation; and
means for biasing the means for discharging current to enable selective current boosting of the read current during the read operation.

23. The SRAM bit cell circuit of claim 21, further comprising:
means for outputting a bias signal to the means for passing a read current;
means for pulling up a voltage at the storage node during a read operation; and
means for biasing the means for pulling up the voltage to enable selective current boosting of the read current during the read operation.

24. The SRAM bit cell circuit of claim 21, further comprising means for outputting a bias signal to the means for passing a read current.

25. The SRAM bit cell circuit of claim 24, further comprising:
means for discharging current from the storage node during a read operation; and
means for biasing the means for discharging current to enable selective current boosting of the read current during the read operation.

26. The SRAM bit cell circuit of claim 24, wherein outputting the bias signal comprises:
means for carrying a bit line charge coupled to the means for passing a read current; and
means for carrying a selective current boost signal; wherein:
the means for outputting a bias signal is configured to output the bias signal if each of a plurality of signals coupled to the means for outputting a bias signal exceeds a trip level;
the means for outputting a bias signal is configured not to output the bias signal if any of the plurality of signals coupled to the input of the means for outputting a bias signal does not exceed the trip level; and
the plurality of signals comprise the bit line charge and selective current boost signal.

27. The SRAM bit cell circuit of claim 26, wherein:
a delay time commences when the means for passing a read current is biased so as to turn on the means for passing a read current, and
the selective current boost signal does not exceed the trip level until the delay time has expired.

28. The SRAM bit cell circuit of claim 26, wherein:
the means for passing a read current comprises a first means for passing a read current to a first storage node and a second means for passing a read current to a second storage node; and
the means for carrying a bit line charge comprises a first means for carrying a bit line charge coupled to the first means for passing a read current and a second means for carrying a bit line charge coupled to the second means for passing a read current.

29. The SRAM bit cell circuit of claim 28, wherein the plurality of signals comprise the first bit line charge, the second bit line charge, and the selective current boost signal.

30. The SRAM bit cell circuit of claim 29, wherein:
a delay time commences when the first and second means for passing a read current are biased so as to turn on the first and second means for passing a read current; and
the selective current boost signal does not exceed the trip level until the delay time has expired.
